(19) United States
(12) Patent Application Publication
(10) Pub. No.: US 2026/0293337 A1
(43) Pub. Date: Sep. 24, 2026

(54) CMOS SENSOR AND METHOD FOR MANUFACTURING A CMOS SENSOR

(71) Applicant: AMS-OSRAM AG, Premstaetten (AT)

(72) Inventors: Joel BERTOMEU MESTRE, OLIVA (ES); Martin FACINELLI, Graz (AT); Rafael SERRANO-GOTARREDONA, Valencia (ES); Jose Manuel GARCIA, San Antonio de Benagéber (ES)

(21) Appl. No.: 19/477,811

(22) PCT Filed: Apr. 18, 2024
(86) PCT No.: PCT/EP2024/060623

§ 371 Date: Oct. 23, 2025

(30) Foreign Application Priority Data
Apr. 25, 2023 (DE) 10 2023 110 543.4

(51) Int. Cl. H10F 39/18; H10F 39/00

(52) U.S. Cl. CPC H10F 39/1895; H10F 39/811

(57) ABSTRACT

CMOS SENSOR AND METHOD FOR MANUFACTURING A CMOS SENSOR A CMOS sensor (10) comprises an active substrate (100) and photodiodes (105). The photodiodes (105) are arranged on a side of a first main surface (102) of the active substrate (100). A terminal of the photodiodes (105) is electrically coupled via the active substrate (100) to a ground line (109) that is electrically coupled to a ground terminal (104), and the ground line (10) is arranged adjacent to a second main surface (103) of the active substrate (100).

### CROSS-REFERENCE TO RELATED APPLICATIONS

This application is a national phase of International Application No. PCT/EP2024/060623 filed on Apr. 18, 2024, which claims priority to German patent application DE 10 2023 110 543.4, which was filed on Apr. 25, 2023, the entire contents of both of which are incorporated herein by reference.

### FIELD OF THE INVENTION

The present disclosure relates to a CMOS sensor and to a method of manufacturing a CMOS sensor.

### BACKGROUND

CMOS (“complementary metal oxide semiconductor”) image sensors are widely used in a variety of applications. A CMOS sensor usually comprises a photodiode for detecting incident electromagnetic radiation. The photodiode and sensor circuitry usually are formed in a silicon substrate. Attempts are being made for improving the performance and the yield when manufacturing CMOS sensors.

### SUMMARY

It is an object of the present invention to provide an improved CMOS sensor and an improved method of manufacturing a CMOS sensor.

According to embodiments, the above object is achieved by the claimed matter according to the independent claims. Further developments are defined in the dependent claims.

According to embodiments, a CMOS sensor comprises an active substrate and photodiodes. The photodiodes are arranged on a side of a first main surface of the active substrate. A terminal of the photodiodes is electrically coupled via the active substrate to a ground line that is electrically coupled to a ground terminal or GND. The ground line is arranged adjacent to a second main surface of the active substrate.

For example, the ground line may form part of or may be implemented by a back side metal layer.

The CMOS sensor may further comprise a logic substrate, wherein logic devices for driving the photodiodes or processing signals are arranged on a side of a first main surface of the logic substrate.

For example, a terminal of at least one logic device is electrically coupled to the ground line via a bond wire coupled to the terminal, the bond wire extending to the first main surface of the active substrate.

The CMOS sensor may further comprise a via contact extending from the first main surface to the second main surface of the active substrate. A terminal of at least one logic device may be electrically coupled to the ground line via a bond wire electrically coupled to the terminal and to the via contact.

According to embodiments, the active substrate and the logic substrate are attached to a conductive sensor substrate. A terminal of at least one logic device is electrically coupled to the ground line via a GND contact pad arranged at a second main surface of the logic substrate facing the conductive substrate.

According to further embodiments, a terminal of at least one logic device may be electrically coupled to the ground line via a GND contact pad arranged at a first main surface of the logic substrate and a bond wire electrically coupled to the conductive sensor substrate and to the GND contact pad.

A method of manufacturing a CMOS sensor comprising an active substrate and photodiodes comprises forming photodiodes at a side of a first main surface of the active substrate, and electrically coupling a terminal of the photodiodes via the active substrate to a ground line that is electrically coupled to a ground terminal. The ground line is arranged adjacent to a second main surface of the active substrate.

The method may further comprise forming a back side metal layer over a second main surface of the active substrate, the ground line forming part of the back side metal layer.

The method may further comprise forming logic devices for driving the photodiodes on a side of a first main surface of a logic substrate.

According to embodiments, the method further comprises electrically coupling a terminal of at least one logic device to the ground line via a bond wire coupled to the terminal, the bond wire extending to the first main surface of the active substrate.

For example, the method further comprises forming a via contact extending from the first main surface to the second main surface of the active substrate. The method further comprises electrically coupling a terminal of at least one logic device to the ground line via a bond wire electrically coupled to the terminal and to the via contact.

According to embodiments, an imaging apparatus comprises the CMOS sensor as described above.

The imaging apparatus may be selected from an image sensor, an X-ray medical imaging apparatus and an imaging apparatus for non-destructive testing.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1A is a cross-sectional view of a CMOS sensor according to embodiments.

FIG. 1B is an example of an equivalent circuit diagram of a pixel of a CMOS sensor.

FIG. 2A is a cross-sectional view of a CMOS sensor according to embodiments.

FIG. 2B is a cross-sectional view of a CMOS sensor according to further embodiments.

FIG. 2C is a cross-sectional view of a CMOS sensor according to further embodiments.

FIG. 2D is a cross-sectional view of a CMOS sensor according to further embodiments.

FIG. 3 summarizes a method according to embodiments.

FIG. 4 shows an imaging apparatus 20 according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes 41 illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “lateral” and “horizontal” as used in this specification intends to describe an orientation parallel to a first surface of a substrate or semiconductor body. This can be for instance the surface of a wafer or a die.

The term “vertical” as used in this specification intends to describe an orientation which is arranged perpendicular to the first surface of a substrate or semiconductor body.

As employed in this specification, the terms “coupled” and/or “electrically coupled” are not meant to mean that the elements must be directly coupled together-intervening elements may be provided between the “coupled” or “electrically coupled” elements. The term “electrically connected” may describe a low-ohmic electric connection between the elements electrically connected together.

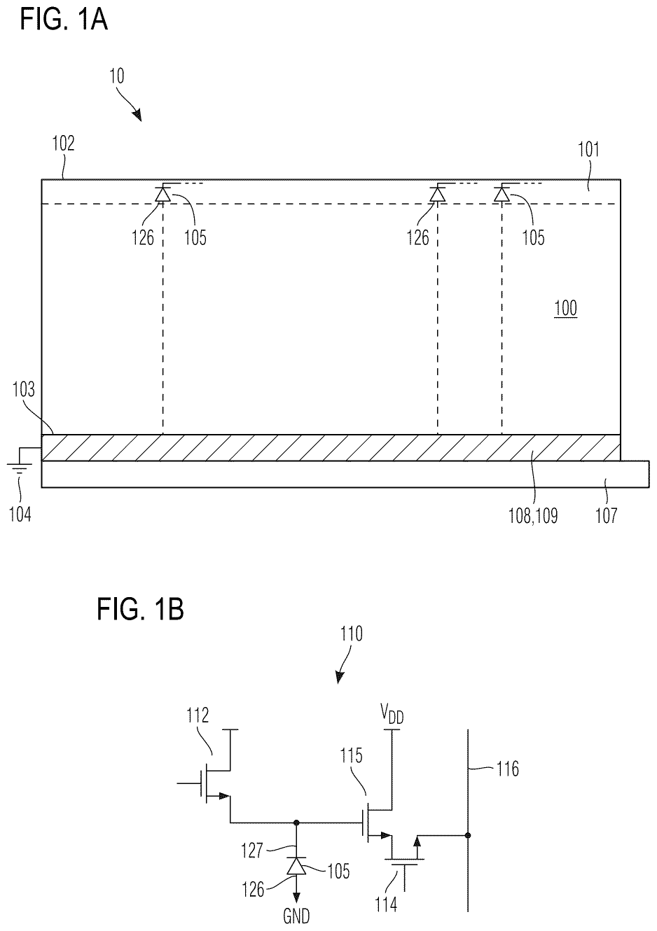

FIG. 1A shows a cross-sectional view of a CMOS sensor 10 according to embodiments. The CMOS sensor 10 comprises an active substrate 100 and photodiodes 105. The photodiodes 105 are arranged on a side of the first main surface 102 of the active substrate 100. A terminal, e.g. an anode terminal 126, of the photodiodes 105 is electrically coupled via the active substrate 100 to a ground line 109 that is electrically coupled to a ground terminal 104. The ground line 109 is arranged adjacent to a second main surface 103 of the active substrate 100. For example, the ground line may form part of a back side metal layer 108 or may be implemented by the back side metal layer 108. The back side metal layer 108 may be arranged adjacent to a second main surface 103 of the active substrate 100. For example, the back side metal layer 108 may be made of a noble metal, e.g. gold. According to examples, the back side metal layer 108 may have a thickness below 1 μm. The metal layer 108 is directly adjacent to the semiconductor material of the active substrate.

For example, the active substrate 100 may be a semiconductor substrate, for example a silicon substrate. For example, the semiconductor substrate may be a p type semiconductor substrate. Accordingly, the metal layer 108 may form a Schottky contact to the semiconductor material of the active substrate 100. For example, layers which may interrupt the connection or current path between the terminal of the photodiode 105 and the metal layer 108 may be absent from the substrate 100. To be more specific, insulating layers or insulating layer portions may be absent from the active substrate 100. Further, doped portions, e.g. buried layer portions, which may form a reverse diode junction may be absent from the active substrate 100.

For example, the photodiodes 105 and further circuit elements for forming a CMOS circuit are arranged in the active area 101 which is adjacent to the first main surface 102 of the active substrate. The active substrate 100 including the back side metal layer 108 may be arranged over a sensor substrate 107. As will be explained in the following, the sensor substrate 107 may be insulating or conductive. The second main surface 103 of the active substrate 100 is facing the sensor substrate 107. The first main surface 102 of the active substrate 100 is remote from the sensor substrate 107.

FIG. 1B shows an example of the sensor circuit 110 that may be arranged in the active area 101. The sensor circuit 110 may comprise the photodiode 105 that comprises a terminal, e.g. anode terminal 126, which is electrically coupled to the ground line 109 and GND via the active substrate 100. Another terminal, e.g. the cathode terminal 127, is connected via a floating diffusion region (not shown in FIG. 1B), to the gate electrode of a readout transistor 115, e.g. a source-follower. A drain terminal of the readout transistor 115 may be electrically coupled to a supply voltage VDD. A source terminal of the readout transistor 115 may be electrically coupled to a drain terminal of a selection transistor 114. A source terminal of the selection transistor 114 may be connected to a column line 116. A source terminal of a reset transistor 112 may be connected to the cathode terminal 127 of the photodiode 105 to perform a reset of the photodiode 105. The sensor circuit 110 illustrated in FIG. 1B implements an active pixel sensor (APS) circuit. As is to be clearly understood, any other circuit suitable for reading out charges generated in the photodiode 105 may be employed.

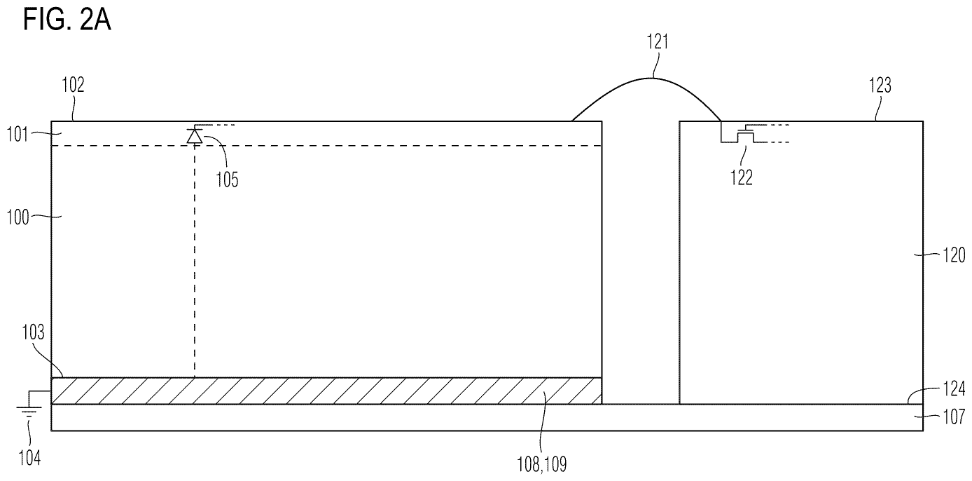

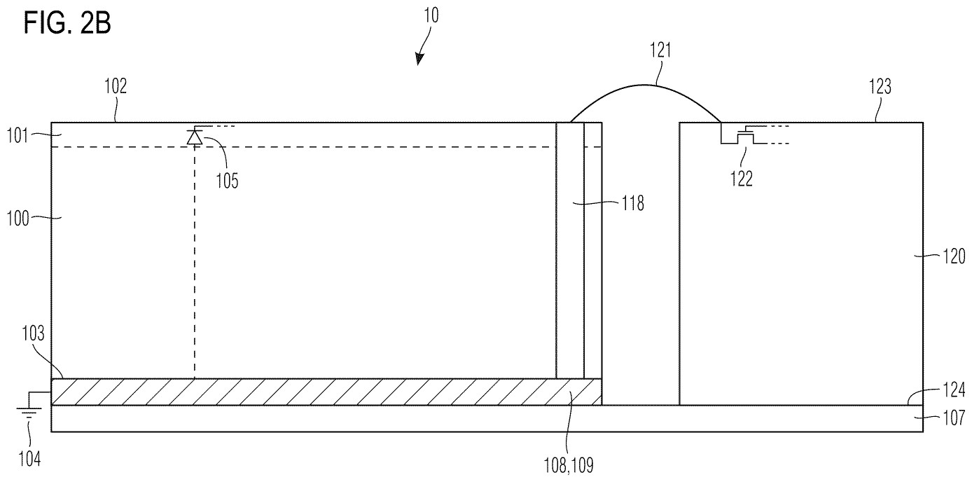

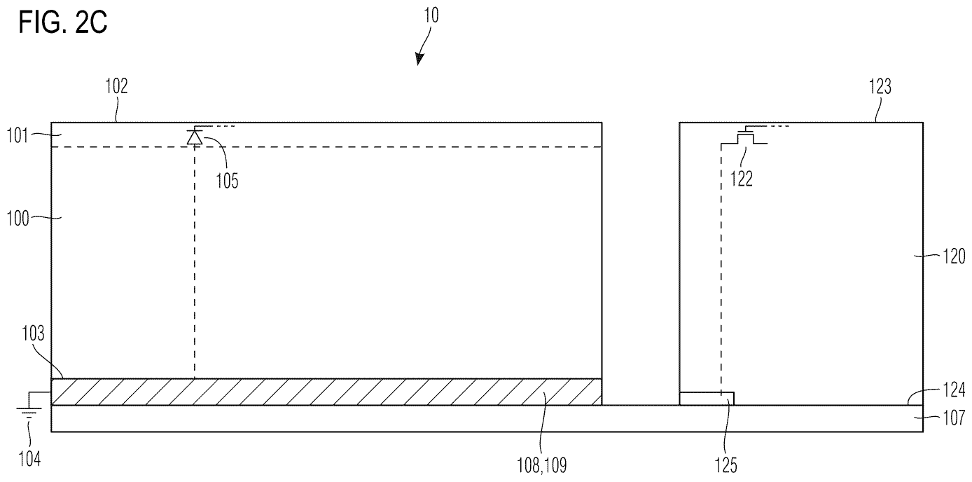

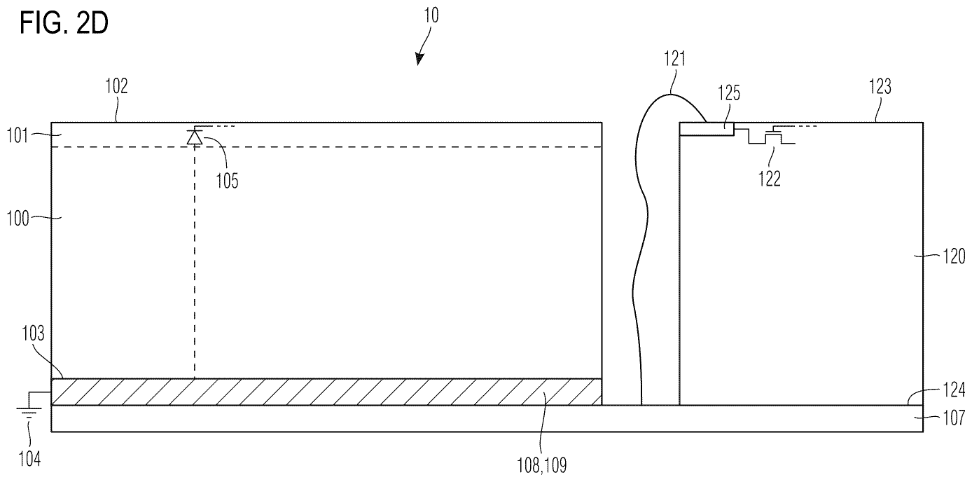

FIG. 2A is a cross-sectional view of a CMOS sensor according to further embodiments. Usually, a CMOS sensor further comprises logic circuitry for driving the circuit elements which are arranged in the active area 101. Further, processing elements for processing signals received from the sensor circuit 110 are arranged in this circuitry. Usually, logic devices 122 that implement the logic circuitry, and the processing elements are arranged in a logic substrate 120, which is different from the active substrate 100. For example, the logic substrate 120 may comprise a PCB (“printed circuit board”) substrate. For example, such a PCB substrate may comprise a laminated sandwich structure comprising conductive and insulating layers.

The logic devices 122 may be arranged on a side of the first main surface 123 of the logic substrate 120. A second main surface 124 of the PCB substrate may be arranged adjacent to the sensor substrate 107. A first main surface 123 of the logic substrate 120 may be remote from the sensor substrate 107.

Usually, terminals of some of the logic devices 122 are also connected to GND.

For example, as is illustrated in FIG. 2A, a terminal of at least one logic device 122 may be electrically coupled to the ground line 109 via a bond wire 121. The bond wire 121 is coupled to the terminal of the logic device 122. The bond wire 121 further extends to the first main surface 102 of the active substrate 100. The bond wire 121 is electrically coupled to the ground line 109 via the semiconductor substrate 100. For example, the Sensor substrate 107 may be made of an insulating material.

FIG. 2B shows a cross-sectional view of a CMOS sensor according to further embodiments. The CMOS sensor illustrated in FIG. 2B comprises similar or identical components as the CMOS sensor 10 illustrated in FIG. 2A. Differing from embodiments illustrated in FIG. 2A, a via contact 118 is formed in the active substrate 100. The via contact 118 extends from a first main surface 102 to a second main surface 103 of the active substrate 100. The via contact 118 is filled with an electrically conductive material, e.g. a metal. As is further shown in FIG. 2B, a terminal of at least one logic device 122 is electrically coupled to the ground line 109 via a bond wire 121. The bond wire 121 is coupled to the terminal and further to the via contact 118. In this way, a low-resistive electrically contact may be accomplished between a terminal of the logic device 122 and the ground line 109 which is arranged adjacent to a second main surface 103 of the active substrate 100.

FIG. 2C shows a cross-sectional view of a CMOS sensor 10 according to further embodiments. The CMOS sensor 10 illustrated in FIG. 2C comprises similar or identical components as the CMOS sensors illustrated in FIGS. 2A and 2B. Differing from embodiments illustrated in FIGS. 2A and 2B, according to embodiments illustrated in FIG. 2C, a terminal of a logic device 122 formed at the first main surface 123 of the logic substrate 120 is electrically connected to a ground contact pad 125. The ground contact pad 125 is arranged adjacent to a second main surface 124 of the logic substrate 120. For example, the logic substrate 120 may comprise conductive portions so that an electrical contact between the terminal of the logic device 122 and the ground contact pad 125 may be accomplished.

The sensor substrate 107 is made of a conductive material. In this way, the terminal of the logic device 122 is electrically connected to the ground terminal 104 via the ground contact pad 125 and the conductive sensor substrate 107. Further, the ground line 109 is arranged at the second main surface 103 of the active substrate 100.

According to embodiments illustrated in FIG. 2D, the CMOS sensor 10 further comprises a ground contact pad 125 which is arranged at the first main surface 123 of the logic substrate 120. A terminal of the logic device 122 is electrically coupled to the ground contact pad 125. The ground contact pad 125 is electrically coupled via a bond wire 121 to the conductive sensor substrate 107. In this way, the terminal of the logic device 122 is electrically coupled to the ground terminal 104 via the ground contact pad 125, the bond wire 121, the conductive sensor substrate 107 and further the ground line 109.

Due to the configurations discussed above, since the ground line 109 is arranged at the second main surface 103 of the active substrate 100, the ground line may be absent from the active area 101. In this way, it is not necessary to route the ground line across the standard CMOS front side metallization. As a consequence, it is possible to alleviate the density of metals on the front side, i.e. the region of the first main surface 102 of the wafer or substrate 100. As a result, the likelihood of a short due to defects may be reduced. Moreover, the production yield may be improved.

When the ground line 109 forms part or is implemented by the back side metal layer 108, the process of manufacturing the CMOS sensor 10 may be further improved.

For example, the CMOS sensor may be an image sensor which may be employed in cameras and others. The image sensor may be employed for medical imaging, e.g. x-ray medical imaging, non-destructive testing and other industrial applications.

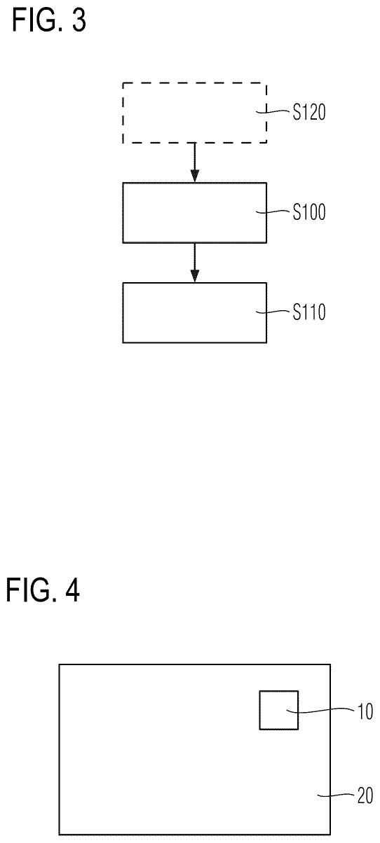

FIG. 3 summarizes a method of manufacturing a CMOS sensor comprising an active substrate 100 and photodiodes 105. As is illustrated, the method comprises forming (S100) photodiodes at a side of a first main surface of the active substrate and electrically coupling (S110) a terminal of the photodiodes via the active substrate to a ground line that is electrically coupled to a ground terminal. The ground line is arranged adjacent to a second main surface 103 of the active substrate 100.

For example, the method may further comprise forming (S120) a back side metal layer 108 adjacent to the second main surface 103 of the active substrate 100. For example, a metal of the back side metal layer may comprise gold. The ground line may form part of or may be implemented by the back side metal layer 108. Thereafter, the photodiodes 105 and further circuit elements of the CMOS sensor may be formed at a side of the first main surface 102, e.g. in the active area 101. This process may be performed so that a terminal of the photodiode 105 is electrically coupled to the back side metal layer 108.

The method may further comprise attaching the active substrate 100 to a sensor substrate 107 so that the second main surface 103 is facing the sensor substrate 107 and the first main surface 102 is remote from the sensor substrate 107.

FIG. 4 shows an imaging apparatus 20 comprising the CMOS sensor 10 which has been explained above. For example, the imaging apparatus 20 may be selected from an image sensor, e.g. a large scale image sensor, an X-ray medical imaging apparatus and an imaging apparatus for non-destructive testing.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

### LIST OF REFERENCES

10 CMOS sensor
20 imaging apparatus
100 active substrate
101 active area
102 first main surface of active substrate
103 second main surface of active substrate
104 ground terminal
105 photodiode
107 sensor substrate
108 back side metal layer
109 ground line
110 sensor circuit
112 reset transistor
114 selection transistor
115 readout transistor
116 column line
118 via contact
120 logic substrate
121 bond wire
122 logic device
123 first main surface of logic substrate
124 second main surface of logic substrate
125 GND contact pad
126 anode terminal
127 cathode terminal

1. A CMOS sensor comprising an active substrate and photodiodes,
wherein the photodiodes are arranged on a side of a first main surface of the active substrate; and
a terminal of the photodiodes is electrically coupled via the active substrate to a ground line that is electrically coupled to a ground terminal, and
the ground line is arranged adjacent to a second main surface of the active substrate;
further comprising a sensor substrate, wherein the active substrate is attached to the sensor substrate so that the second main surface is facing the sensor substrate and the first main surface is remote from the sensor substrate.

2. The CMOS sensor according to claim 1, wherein the ground line forms part of a back side metal layer.

3. The CMOS sensor according to claim 1, further comprising a logic substrate, wherein logic devices for driving the photodiodes or processing signals are arranged on a side of a first main surface of the logic substrate and the logic substrate is attached to the sensor substrate so that the first main surface of the logic substrate is remote from the sensor substrate.

4. The CMOS sensor according to claim 3, wherein a terminal of at least one logic device is electrically coupled to the ground line via a bond wire coupled to the terminal, the bond wire extending to the first main surface of the active substrate.

5. The CMOS sensor according to claim 3, further comprising a via contact extending from the first main surface to the second main surface of the active substrate, wherein a terminal of at least one logic device is electrically coupled to the ground line via a bond wire electrically coupled to the terminal and to the via contact.

6. The CMOS sensor according to claim 3, wherein the sensor substrate is a conductive sensor substrate, and a terminal of at least one logic device is electrically coupled to the ground line via a GND contact pad arranged at a second main surface of the logic substrate facing the conductive sensor substrate.

7. The CMOS sensor according to claim 3, wherein the sensor substrate is a conductive sensor substrate, and a terminal of at least one logic device is electrically coupled to the ground line via a GND contact pad arranged at the first main surface of the logic substrate and a bond wire electrically coupled to the conductive sensor substrate and to the GND contact pad.

8. A method of manufacturing a CMOS sensor comprising an active substrate and photodiodes, the method comprising:
forming photodiodes at a side of a first main surface of the active substrate;
electrically coupling a terminal of the photodiodes via the active substrate to a ground line that is electrically coupled to a ground terminal, wherein the ground line is arranged adjacent to a second main surface of the active substrate; and
attaching the active substrate to a sensor substrate so that the second main surface is facing the sensor substrate and the first main surface is remote from the sensor substrate.

9. The method according to claim 8, further comprising forming a back side metal layer over the second main surface of the active substrate, the ground line forming part of the back side metal layer.

10. The method according to claim 8, further comprising forming logic devices configured to drive the photodiodes on a side of a first main surface of a logic substrate.

11. The method according to claim 10, further comprising electrically coupling a terminal of at least one logic device to the ground line via a bond wire coupled to the terminal, the bond wire extending to the first main surface of the active substrate.

12. The method according to claim 10, further comprising forming a via contact extending from the first main surface to the second main surface of the active substrate, and electrically coupling a terminal of at least one logic device to the ground line via a bond wire electrically coupled to the terminal and to the via contact.

13. An imaging apparatus comprising a CMOS sensor comprising an active substrate and photodiodes,
wherein the photodiodes are arranged on a side of a first main surface of the active substrate; and
a terminal of the photodiodes is electrically coupled via the active substrate to a ground line that is electrically coupled to a ground terminal, and
the ground line is arranged adjacent to a second main surface of the active substrate;
further comprising a sensor substrate, wherein the active substrate is attached to the sensor substrate so that the second main surface is facing the sensor substrate and the first main surface is remote from the sensor substrate.

14. The imaging apparatus according to claim 13, being selected from an image sensor, an X-ray medical imaging apparatus and an imaging apparatus for non-destructive testing.
